(19) United States
(12) Patent Application Publication
(10) Pub. No.: US 2005/0110126 A1
(43) Pub. Date: May 26, 2005

(54) Chip adhesive

(76) Inventor: Kai-Chiang Wu, Hsin Chu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/720,524

(22) Filed: Nov. 25, 2003

(51) Int. Cl. H01L 21/48; H01L 23/02

(52) U.S. Cl. 257/686; 438/109; 257/782; 438/118

(57) ABSTRACT

The claimed invention discloses a chip adhesive that is adhered to a stacked packaging structure between two adjacent chips. The chip adhesive includes a plurality of stuff particles to keep the chip adhesive with a predetermined thickness through suitably controlling type and quantity of the stuff particle. Two adjacent chips can be adhered together with a specific gap. The cost of dummy die can be saved and the space for wiring bonding can be retained. The chips of the stacked packaging structure, moreover, can be packaged with a faced-up type to reduce the cost of applying flip chip type or WBGA type.

### BACKGROUND OF INVENTION

1. Field of the Invention

The present invention relates to a chip adhesive, and more particularly, to a chip adhesive applied to a stacked packaging structure.

2. Description of the Prior Art

The stacked packaging technology means stacking a plurality of chips, electrically connecting each chip, and packaging these chips to an IC. As shown in FIG. 1, when the size of the lower chip 10 is equal to or smaller than that of the upper chip 12, a gap between two chips 10, 12 is required to bond the lower wiring 14. A dummy die 16 is located between two chips 10, 12 and utilizing a adhesive 18 to adhere to the chips 10, 12 to keep the chips 10, 12 a enough distance for wiring.

Please refer to FIG. 2, which is a schematic diagram illustrating another packaging structure according to the prior art. The upper chip 12 retains facing up, and the lower chip 10 is packaged in a flip chip type. The adhesive 18 can adhere two chips 10, 12 without problem of insufficient space for wiring bonding. But the bonding processes of the lower chip 10 and the upper chip 12 are different and requiring different machines. This kind of packaging structure has complicated process and high cost.

Besides these two conventional packaging technologies, a window ball grid array (WBGA) technology is shown in FIG. 3. The upper chip 12 retains facing up, and the lower chip 10 is wire bonded through windows on the substrate 20. This technology does not need a dummy die to keep distance between two chips 10, 12, but the bonding processes of two chips are different and also requiring different machines. Thus, this kind of packaging structure also has complicated process and high cost.

### SUMMARY OF INVENTION

It is therefore a primary objective of the claimed invention to provide a chip adhesive, which can adhere to a stacked packaging structure between two adjacent chips and keep these two chips with a predetermined thickness to save the cost of dummy die.

It is therefore another objective of the claimed invention to provide a stacked packaging structure utilizing a chip adhesive, which can keep these two chips with a predetermined thickness to save the cost of dummy die.

According to the claimed invention, a chip adhesive is adhered to a stacked packaging structure between two adjacent chips. The chip adhesive includes a plurality of stuff particles to keep the chip adhesive with a predetermined thickness through suitably controlling type and quantity of the stuff particle. Two adjacent chips can be adhered together with a specific gap. The cost of dummy die can be saved and the space for wire bonding can be retained. In addition, the stacked packaging structure utilizing the chip adhesive is constructed on an packaging substrate, and the stacked packaging structure has a plurality of chips stacked from bottom to top. Two adjacent chips are adhered together with the claimed chip adhesive within a specific gap.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 to 3 are schematic diagrams showing stacked packaging structures according to the prior art.

FIG. 4 to 6 are schematic diagrams showing stacked packaging structures according to the present invention.

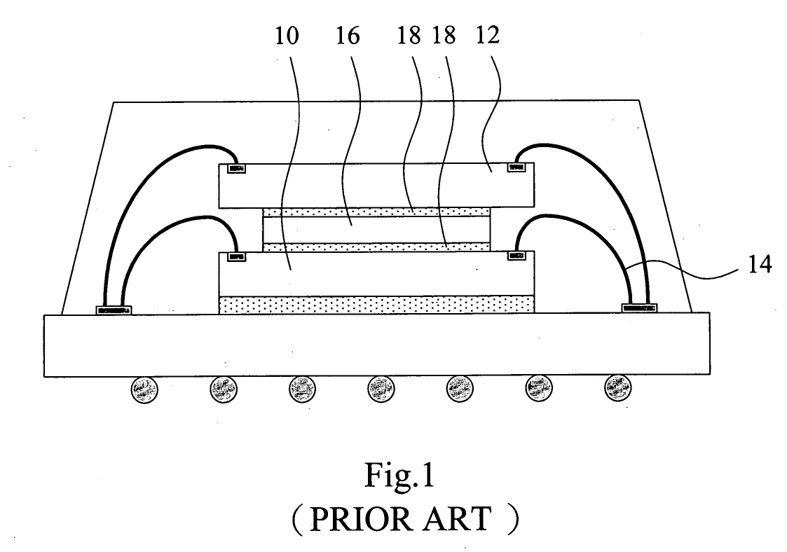

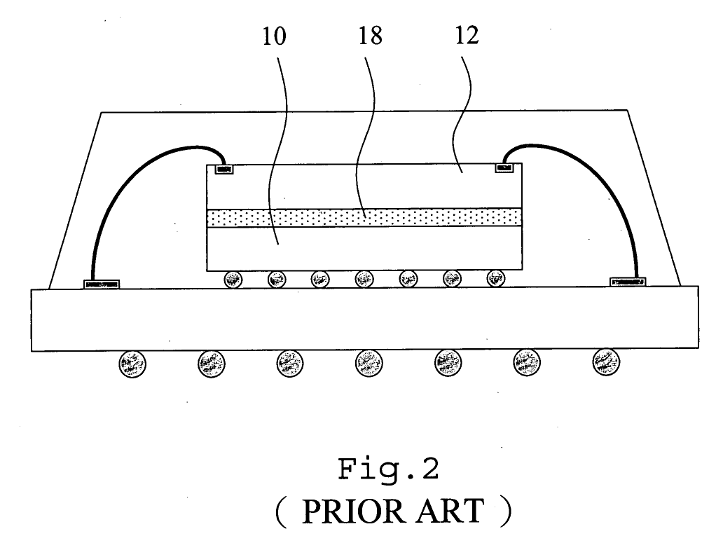

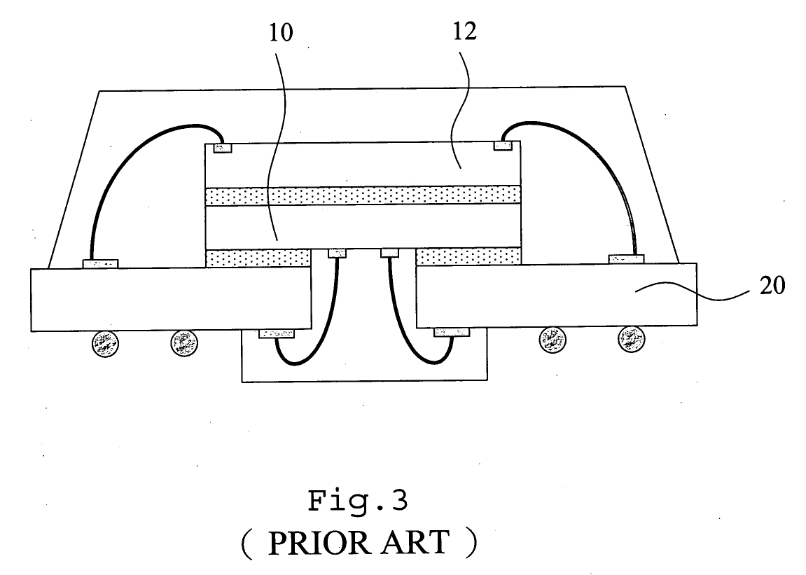

### DETAILED DESCRIPTION

The claimed invention discloses a chip adhesive and a stacked packaging structure applying it. The chip adhesive includes a plurality of stuff particles to keep the chip adhesive with a predetermined thickness and keep two adjacent chips with a specific gap. The thickness of the chip adhesive can be changed with stuffing different type or quantity of stuff particles to flexibly using the present invention.

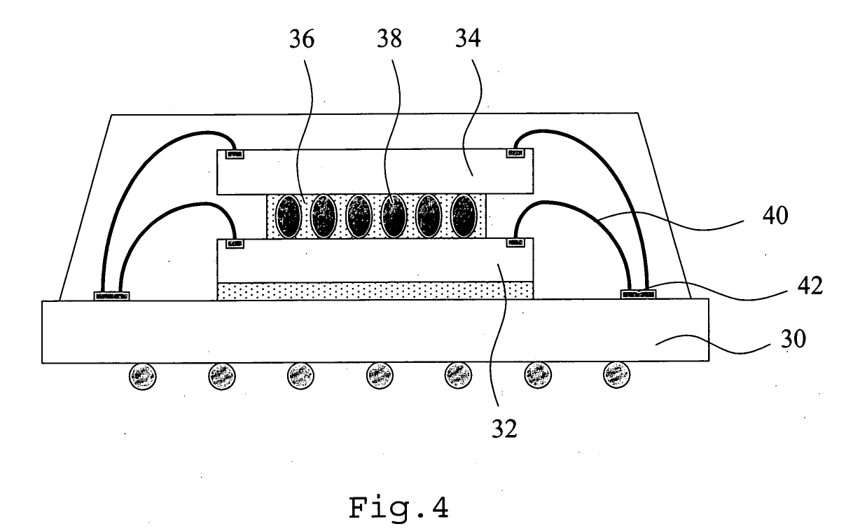

Please refer to FIG. 4, which is a schematic diagram of an embodiment according to present invention. A stacked packaging structure is constructed on an packaging substrate 30, and the stacked packaging structure has a lower chip 32 and an upper chip 34 with same size. These two chips 32, 34 are adhered together with a chip adhesive 36, and the chip adhesive 36 includes a plurality of stuff particles 38 to keep the chip adhesive 36 with a predetermined thickness. The thickness of the chip adhesive 36 can be changed through suitably selecting types and quantities of the stuff particle 38. With the chip adhesive 36, two adjacent chips 32, 34 can be adhered together with a specific gap, and a sufficient bonding space for a lower wiring 40 can be retained to connect to a golden finger 42.

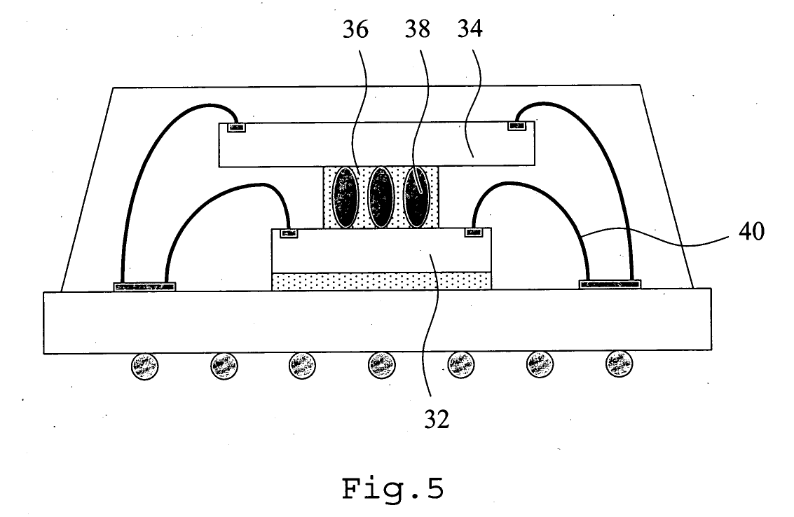

Please refer to FIG. 5, when the size of the lower chip 32 is smaller than that of the upper chip 34, the gap between two chips 32, 34 is absolutely required for the lower wiring 40. If a larger gap between two chips 32, 34 is needed for successfully bonding, the stuff particle 38 can be selected larger to enhance the thickness of the chip adhesive 36. The suitable gap can be retained with selecting the suitable size of the stuff particle 38.

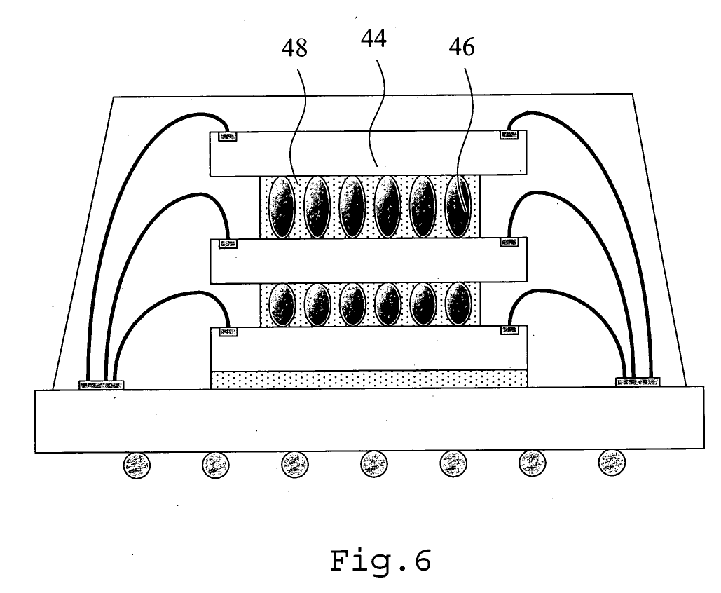

In addition, as shown in FIG. 6, the claimed invention can be further applied to a stacked packaging structure with multi chips 44. The various stuff particles 46 can be selected for different needed gaps between each two chips 44, and keep the adjacent chips with different distances.

In contrast to the prior art, the present invention can adhere chips and retain a suitable gap simultaneously, so that the cost of dummy die can be saved and the various applied flexibilities of thickness between chips can be improved. Furthermore, the present invention can be applied to not only the situation that the size of the lower chip is equal to or smaller than that of the upper chip but also any requirements for retaining a specific distance between two adjacent chips.

Those skilled in the art will readily observe that numerous modifications and alterations of the device may be made while retaining the teachings of the invention. Accordingly, the above disclosure should be construed as limited only by the metes and bounds of the appended claims.

1. A chip adhesive adhered to a stacked packaging structure between two adjacent chips, and the chip adhesive includes a plurality of stuff particles to keep the chip adhesive with a predetermined thickness.

2. The chip adhesive of claim 1 can further control the thickness through suitably selecting a type of the stuff particle.

3. The chip adhesive of claim 1 can further control the thickness through suitably selecting a quantity of the stuff particle.

4. A stacked packaging structure utilizing a chip adhesive, comprising:
a stacked packaging structure constituted on an substrate, and the stacked packaging structure has a plurality of chips stacked from bottom to top; and
a chip adhesive adhered between these two adjacent chips, and the chip adhesive includes a plurality of stuff particles to keep the chips with a predetermined thickness.

5. The stacked packaging structure of claim 4 can further control the thickness through suitably selecting a type and a quantity of the stuff particle.
